(19) United States
(12) Patent Application Publication
(10) Pub. No.: US 2012/0286818 A1
(43) Pub. Date: Nov. 15, 2012

(54) ASSEMBLY FOR OPTICAL BACKSIDE FAILURE ANALYSIS OF WIRE-BONDED DEVICE DURING ELECTRICAL TESTING

(75) Inventors: Himaja H. Bhatt, Cardiff by the Sea, CA (US); Martin E. Parley, Carlsbad, CA (US)

(73) Assignee: QUALCOMM INCORPORATED, San Diego, CA (US)

(21) Appl. No.: 13/105,732

(22) Filed: May 11, 2011

(51) Int. Cl. G01R 31/00

(52) U.S. Cl. 324/756.02

(57) ABSTRACT

Systems, methods, devices, and computer program products are described for allowing optical backside failure analysis of a wire-bonded semiconductor device concurrent with electrical testing of the device. For example, a semiconductor device is prepared and mounted in the optical testing subsystem, such that a circuit region of the device is exposed to an optical testing environment, and an analog to the original array of the device is presented via the optical testing subsystem as a derived array. The electrical testing subsystem converts the derived array to a test array, and presents the test array in a way that is physically and electrically compatible with a test socket of an electrical testing environment. By coupling the electrical testing subsystem with the optical testing subsystem, a pin-to-pin coupling may be effectuated between the test array of the test socket and bonding locations on the device corresponding to the device's original array.

### BACKGROUND

The disclosure relates generally to semiconductor device testing and, more particularly, to optical backside failure analysis of wire-bonded semiconductor devices.

Various types of semiconductor device testing are available for determining different potential types of failure modes and other issues. These types of testing include electrical testing and backside failure analysis. Electrical testing typically involves interfacing the device array (e.g., the package grid array or solder ball array on the backside of the device) with electrical testing equipment, for example, via a test socket. In certain cases, backside failure analysis of the device is performed depending on the failing mode (e.g., from the electrical testing).

Backside failure analysis typically involves using optical equipment to detect issues with the device. For example, the backside of a wire-bonded die may be exposed to the optical analysis equipment by milling away the device array and a portion of the substrate and polishing the die. An analysis tool including an optical objective (e.g., a solid immersion lens) comes in contact with the backside of the die and travels all the way to the edges of the die for analysis (e.g., of individual transistors, of thermal patterns, etc.).

Accordingly, preparing the device for backside failure analysis may cause it to be difficult or impossible to concurrently (or subsequently) perform electrical testing. For example, traditional electrical testing interfaces may incompatible with the device after milling away the device array and/or when the die needs to remain exposed to the optical testing equipment.

### SUMMARY

The present disclosure is directed to systems and methods that allow for optical backside failure analysis of a wire-bonded semiconductor device concurrent with electrical testing of the device. Embodiments include an electrical testing subsystem configured to couple with an optical testing subsystem to form an optical-electrical device testing system. Some embodiments further include the optical testing subsystem.

In one exemplary configuration, the semiconductor device is prepared and mounted in the optical testing subsystem, such that a circuit region of the device is exposed to an optical testing environment (e.g., a solid immersion lens) via a prepared backside, and an analog of the original array of the device is presented via the optical testing subsystem as a derived array. The electrical testing subsystem is configured to convert the derived array to a test array, and to present the test array in a way that is physically and electrically compatible with a test socket of an electrical testing environment. By coupling the electrical testing subsystem with the optical testing subsystem, a pin-to-pin coupling may be effectuated between the test array of the test socket an bonding locations on the device corresponding to the device's original array.

An exemplary system includes an electrical test assembly, which has: a carrier interface module having a first derived array on a surface physically configured to allow electrical coupling between the first derived array and a second derived array disposed on a carrier, and configured to translate the first derived array to a first test array determined according to a second test array of a test socket of an electrical testing environment; and a test socket interface module, coupled with the carrier interface module and configured to physically couple with the test socket so as to provide an electrical coupling between the first test array and the second test array. Embodiments of such a system further include an optical test assembly that has: a carrier, physically coupled with a first side of a semiconductor device so as to present a circuit region of the device to an optical testing environment via a prepared second side of the device, the carrier being electrically coupled with the device such that the circuit region of the device is in electrical communication with bonding locations of the carrier according to an original array of the device; and an electrical test interface configured to physically and electrically couple the second derived array with the first derived array disposed on the carrier interface of the electrical test assembly.

Also or alternatively, the electrical test interface has a carrier socket configured to physically and electrically couple with the carrier and to physically and electrically couple the second derived array with the first derived array disposed on the carrier interface of the electrical test assembly by providing an optical-electrical coupling region. Also or alternatively, the electrical test interface has a lid configured to secure the carrier to the carrier socket so as to ensure the electrical coupling between the carrier and the carrier socket while presenting the circuit region of the device to the optical testing environment. Also or alternatively, the optical test assembly is coupled with the electrical test assembly to provide an electrical coupling between the bonding locations of the carrier and the second test array of the test socket.

In some such systems, the test socket interface module has a number of pins, arranged according to the second test array, extending through a housing, and protruding from each of a first side and a second side of the housing, the first side of the housing configured to physically couple with the carrier interface module to provide an electrical coupling between each of the pins and a corresponding element of the first test array, and the second side of the housing configured to physically couple with the test socket to provide an electrical coupling between each of the pins and a corresponding element of the second test array.

Another exemplary system includes means for providing a pin-to-pin electrical coupling between a semiconductor device and an electrical testing environment while presenting a circuit region of the device to an optical testing environment via a prepared backside of the device, the circuit region in electrical communication with bonding locations according to an original array of the device.

In some such systems, the means for providing a pin-to-pin electrical coupling between the semiconductor device and the electrical testing environment while presenting the circuit region of the device to the optical testing environment has: means for physically coupling with the device so as to present the exposed circuit region of the device to the optical testing environment while electrically coupling the bonding locations of the device with a derived array; means for physically interfacing with a test socket of the electrical testing environment while electrically coupling with a test array of the test socket; and means for electrically translating the derived array to the test array, such that the bonding locations of the device are electrically coupled with the test socket of the electrical testing environment.

Also or alternatively, the test socket is configured to directly interface with a packaging of the device via a pin-to-pin electrical coupling between the test array and the original array of the device presented via the packaging. Also or alternatively, the system further includes means for securing the means for physically interfacing with the test socket of the electrical testing environment while electrically coupling with the test array of the test socket to the means for electrically translating the derived array to the test array.

In some embodiments, the means for physically coupling with the device so as to present the exposed circuit region of the device to the optical testing environment while electrically coupling the bonding locations of the device with a derived array has: means for physically coupling a topside of the device with a first side of a carrier; and means for electrically coupling each bonding location of the device to one of a plurality of bonding locations on a first side of the carrier, each bonding location on the first side of the carrier being in electrical correspondence with an electrical interface element on the second side of the carrier arranged according to the derived array. Also or alternatively, the means for electrically translating the derived array to the test array has: a carrier interface comprising a plurality of electrical interface elements arranged according to the derived array and configured to interface with the second side of the carrier so as to electrically couple each electrical interface element of the carrier interface with a corresponding one of the electrical interface elements of the second side of the carrier; and a first intermediate interface comprising a plurality of electrical interface elements arranged according to the test array, each electrical interface element of the first intermediate interface being electrically coupled with a corresponding one of the electrical interface elements of the carrier interface; and the means for physically interfacing with the test socket of the electrical testing environment while electrically coupling with the test array of the test socket has: a second intermediate interface comprising a plurality of electrical interface elements arranged according to the test array and configured to interface with the first intermediate interface so as to electrically couple each electrical interface element of the second intermediate interface with a corresponding one of the electrical interface elements of the first intermediate interface; and a socket interface comprising a plurality of electrical interface elements arranged according to the test array, each electrical interface element of the socket interface being electrically coupled with a corresponding one of the electrical interface elements of the second intermediate interface.

An exemplary method includes providing a pin-to-pin electrical coupling between a semiconductor device and an electrical testing environment while presenting a circuit region of the device to an optical testing environment via a prepared backside of the device, the circuit region in electrical communication with bonding locations according to an original array of the device. Also or alternatively, providing the pin-to-pin electrical coupling between the semiconductor device and the electrical testing environment while presenting the circuit region of the device to the optical testing environment includes: physically coupling with the device so as to present the exposed circuit region of the device to the optical testing environment while electrically coupling the bonding locations of the device with a derived array; physically interfacing with a test socket of the electrical testing environment while electrically coupling with a test array of the test socket; and electrically translating the derived array to the test array, such that the bonding locations of the device are electrically coupled with the test socket of the electrical testing environment.

In some embodiments, the method further includes: securing a test socket interface module to a carrier interface module, wherein the physically interfacing step is performed using the test socket interface module and the electrically translating step is performed using the carrier interface module. Also or alternatively, physically coupling with the device so as to present the exposed circuit region of the device to the optical testing environment while electrically coupling the bonding locations of the device with a derived array includes: physically coupling a topside of the device with a first side of a carrier; and electrically coupling each bonding location of the device to one of a plurality of bonding locations on a first side of the carrier, each bonding location on the first side of the carrier being in electrical correspondence with an electrical interface element on the second side of the carrier arranged according to the derived array.

The foregoing has outlined rather broadly the features and technical advantages of embodiments of the present disclosure in order that the detailed description that follows may be better understood. Additional features and advantages will be described hereinafter. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the spirit and scope of the appended claims. The novel features which are believed to be characteristic of the concepts disclosed herein, both as to their organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the claims.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a block diagram of an exemplary semiconductor testing environment;

FIG. 2 illustrates an exemplary chip to provide added clarity to the description;

FIG. 3 shows an exemplary interface assembly, including an optical test assembly and an electrical test assembly;

FIG. 4A illustrates an exemplary configuration of an electrical test assembly, like the one described with reference to FIG. 3;

FIG. 4B illustrates another exemplary configuration of an electrical test assembly, like the one described with reference to FIG. 3;

FIG. 5A illustrates an exemplary configuration of an optical test assembly, like the one described with reference to FIG. 3;

FIG. 5B illustrates another exemplary configuration of an optical test assembly, like the one described with reference to FIG. 3;

FIG. 6 illustrates a method for concurrent optical and electrical testing of a semiconductor device;

FIG. 7 illustrates another method for concurrent optical and electrical testing of a semiconductor device that expands on the method of FIG. 6; and

FIG. 8 illustrates yet another method for concurrent optical and electrical testing of a semiconductor device that expands on the method of FIG. 7.

### DETAILED DESCRIPTION

Techniques are described for allowing optical backside failure analysis of a wire-bonded semiconductor device concurrent with electrical testing of the device. As used herein, the phrase “semiconductor device” is intended to broadly include semiconductor integrated circuits (ICs) and/or other similar components. For example, a semiconductor device is prepared and mounted in the optical testing subsystem, such that a circuit region of the device is exposed to an optical testing environment (e.g., a solid immersion lens) via a prepared backside, and an analog to the original array of the device is presented via the optical testing subsystem as a derived array. The electrical testing subsystem is configured to convert the derived array to a test array, and to present the test array in a way that is physically and electrically compatible with a test socket of an electrical testing environment. By coupling the electrical testing subsystem with the optical testing subsystem, a pin-to-pin coupling may be effectuated between the test array of the test socket an bonding locations on the device corresponding to the device's original array.

Thus, the following description provides examples, and is not limiting of the scope, applicability, or configuration set forth in the claims. Changes may be made in the function and arrangement of elements discussed without departing from the spirit and scope of the disclosure or claims. Various examples may omit, substitute, or add various procedures or components as appropriate. For instance, the methods described may be performed in an order different from that described, and various operations may be added, omitted, or combined. Also, features described with respect to certain examples may be combined in other examples.

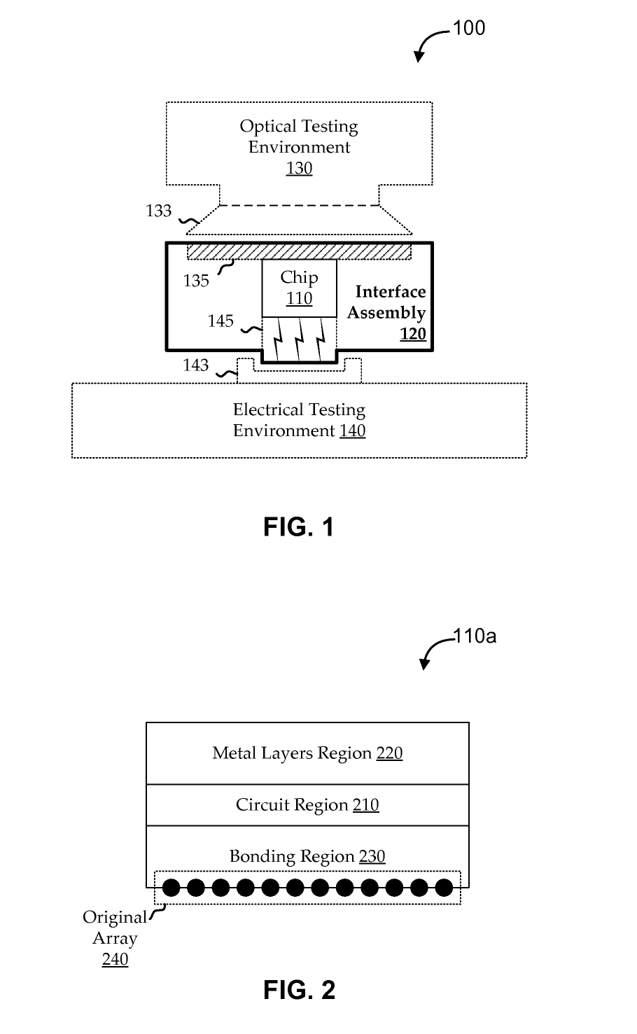

Referring first to FIG. 1, a block diagram illustrates an example of a semiconductor testing environment 100. The semiconductor testing environment 100 includes an optical testing environment 130 and an electrical testing environment 140 for testing a chip 110. As described more fully below, the chip 110 is typically prepared in a particular way to facilitate optical backside failure analysis using the optical testing environment 130. This type of preparation may affect (e.g., destroy) portions of the chip 110 typically used to interface with standard electrical testing equipment of the electrical testing environment 140.

Traditional techniques may find it difficult or impossible to provide concurrent electrical and optical testing of the chip 110. For example, according to one traditional approach, optical and electrical testing may be performed independently, for example, at different times using different equipment and different interfaces. According to other traditional approaches, highly specialized interfaces may be constructed for each type of chip 110, each type of electrical testing environment 140, etc.

As illustrated, an interface assembly 120 is provided to interface with both the optical testing environment 130 and the electrical testing environment 140 for concurrent testing of the chip 110. For example, the chip 110 is exposed to the optical testing environment 130 via an optical interface region 135, and the chip 110 is exposed to the electrical testing environment 140 via an electrical interface region 145. The configuration of the interface assembly allows desired preparation of the chip 110 circuitry for optical analysis using the optical testing environment 130, while also providing desired access to the chip 110 circuitry for electrical testing via standard test equipment interfaces.

The chip may be any wire-bonded type of semiconductor device. FIG. 2 illustrates an exemplary chip 110a to provide added clarity to the description. The chip 110a illustrated in FIG. 2 should not be construed as limiting, as other configurations of chips may be used with the techniques described herein without departing from the scope of the description or the claims.

The illustrative chip 110a includes various regions, including a circuit region 210, a metal layers region 220, a bonding region 230, and an array 240. The circuit region 210 may include circuit elements (e.g., transistors, etc.) to support the underlying functionality of the chip 110a. For example, the circuit region 210 may typically include multiple semiconductor elements formed on a substrate (e.g., a silicon wafer) by one or more so-called “front-end” processes, like deposition, patterning, removal, doping, annealing, etc.

After the circuit region 210 has been formed, it may be packaged into the chip 110a package using other processes (e.g., “back end of line” processes). For example, various circuit elements in the circuit region 210 may be interconnected using metal interconnects that are insulated using dielectrics. Particularly in complex chip 110a architectures, large numbers of metal interconnects may result in multiple metal layers in the metal layers region 220 of the chip 110a.

To provide access to portions of the circuit region 210 (e.g., for input/output functionality, for external loading or signaling, electrical testing, etc.), bonding locations in the circuit region 210 are bonded via the bonding region 230 to the array 240. The array 240 may be a solder ball array (SBA) or other type of array. As described below, various techniques described herein involve additional arrays. Accordingly, for the sake of clarity, the array 240 of the chip 110a is referred to herein as the “original” array 240.

Electrical testing of the chip 110a may typically be performed by coupling the chip 110a with a test socket of electrical testing equipment, so that the original array 240 forms a pin-to-pin connection with a test array on the test socket. For example, the socket includes a number of contact elements arranged according to the original array 240. The chip 110a is inserted into the socket, causing each solder ball of the SBA forming the original array 240 to electrically couple with a corresponding one of the contact elements of the test socket.

Backside failure analysis may typically use optical equipment (e.g., light sources, lasers, solid immersion lenses, microscopes, etc.) to perform failure analysis of the circuit region 210 of the chip 110a. For example, optical techniques can be used to see thermal patterns, light emissions, changes in transistor behavior (e.g., when a laser is shined on the transistor), etc. To provide optical access to the circuit region 210, the circuit region 210 is first exposed. It may be difficult or impossible to perform many optical techniques from the front side of the chip 110a due, for example, to the metal layers region 220.

Accordingly, the circuit region 210 is typically revealed by preparing the backside of the chip 110a. For example, the original array 240 (e.g., the SBA), the bonding region 230, and a portion of the packaging and substrate are removed (e.g., milled and polished), thereby revealing the circuit region 210. Optical failure analysis can then be performed on the circuit region 210 of the chip 110a via its prepared backside.

Notably, preparing the backside of the chip may involve removing the original array 240, which may interfere with physically and/or electrically coupling the chip 110a with a standard test socket. Further, electrical testing may involve contact with the backside of the chip, which may interfere with keeping the backside of the chip 110a (i.e., the exposed circuit region 210) visible to optical test equipment. These and other issues can frustrate concurrent optical and electrical testing of the chip 110a.

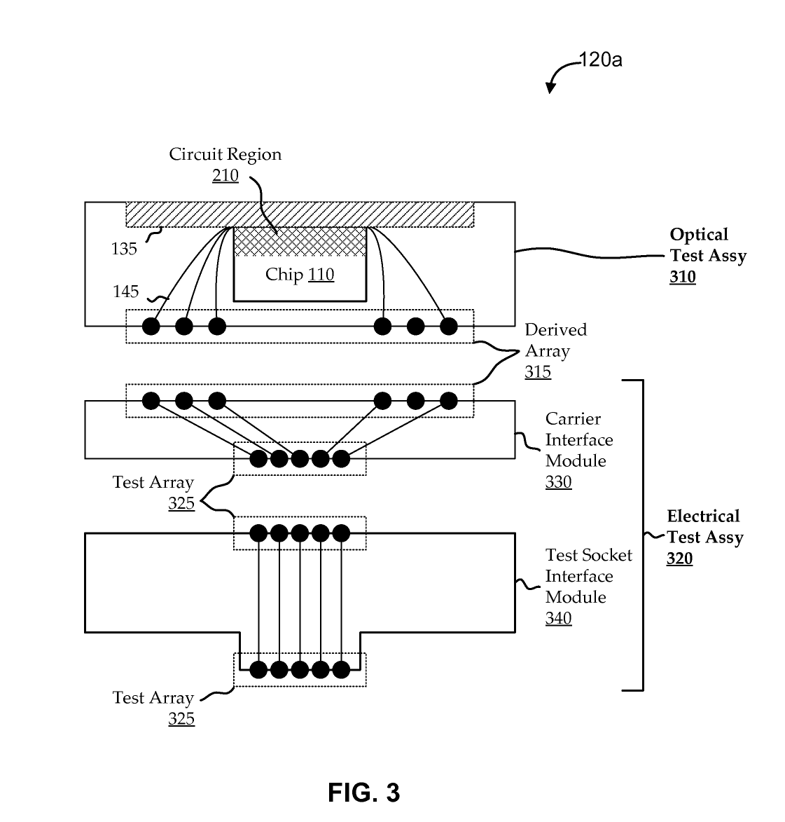

As discussed above with reference to FIG. 1, embodiments of interface assemblies 120 allow for concurrent optical and electrical testing of the chip 110a. Various exemplary components of interface assemblies 120 are described with reference to FIGS. 3-5B. The exemplary components are provided to illustrate certain types of functionality of interface assemblies 120, like the one described in FIG. 1. Many variations to the exemplary components are possible, and, accordingly, the descriptions should not be construed as limiting the scope of the invention or the claims.

Turning to FIG. 3, an exemplary interface assembly 120a is shown, including an optical test assembly 310 and an electrical test assembly 320. The optical test assembly 310 is configured to optically expose a circuit region 210 of a chip 110 to an optical component (e.g., a solid immersion lens) of an optical testing environment (not shown) while electrically exposing the circuit region 210 of the chip 110 to the electrical test assembly 320. The electrical test assembly 320 is configured to electrically expose the circuit region 210 of the chip 110 (via the optical test assembly 310) to a standard electrical interface (e.g., a test socket) of an electrical testing environment (not shown).

As described above, the chip 110 may be prepared (e.g., by milling and polishing) to expose its circuit region 210 via a removed portion of the backside of the chip 110 packaging. The chip 110 is then presented by the optical test assembly 310 such that the exposed circuit region 210 is facing the optical testing environment. Optical testing equipment can then interact with the chip 110 through an optical interface region 135. For example, the optical interface region 135 can be an opening, a lens, etc.

In addition to optically exposing the chip 110 to an optical testing environment, the optical test assembly 310 is configured to provide a derived array 315 for electrical coupling with the chip 110. As described with reference to FIG. 2, the original array 240 is bonded to portions of the circuit region 210 of the chip 110 for various purposes. After removing the original array 240 during the backside preparation process, the original bonding locations (e.g., and/or other locations that may or may not correspond to the original array 240) are exposed. These bonding locations may be electrically coupled (e.g., wire bonded) with a set of bonding locations on a circuit board or other type of carrier. For example, the chip may be mounted upside-down on the carrier to optically expose the circuit region 210 while also wire bonding the circuit region 210 to bonding locations on the carrier to electrically couple the circuit region (e.g., according to the original array 240) with the derived array 315.

The derived array 315 may be implemented using solder balls, pins, and/or any other type of electrical contact elements. In some configurations, a portion of the optical test assembly 310 is implemented using a standard component having a standard derived array 315. For example, the carrier may be implemented as a printed circuit board (PCB) having the bonding locations on one side and an SBA on the opposite side.

Exemplary configurations of the electrical test assembly 320 interface with the derived array 315 of the optical test assembly 310 while electrically exposing the derived array 315 to a standard electrical interface (e.g., a test socket) of an electrical testing environment (not shown). As illustrated, the electrical test assembly 320 may include a carrier interface module 330 and a test socket interface module 340. The modules of the electrical test assembly 320 may be integrated according to certain configurations, as described more fully below.

The carrier interface module 330 includes a derived array 315 configured to interface with the derived array 315 of the optical test assembly 310, a test array 325 configured to interface with a test array 325 on the test socket interface module 340, and couplings between the derived array 315 and the test array 325. According to some configurations, the carrier interface module 330 is a PCB designed to translate the derived array 315 to the test array 325 (e.g., using internal connections of the PCB). For example, the PCB may include pogo pins, pads, solder balls, and/or any other type of electrical contact components, used to electrically couple the derived array 315 of the electrical test assembly 320 with the derived array 315 of the optical test assembly 310 and/or to electrically couple the test array 325 of the carrier interface module 330 with the test array 325 of the test socket interface module 340.

The test socket interface module 340 is configured provide an interface between the carrier interface module 330 and an interface that is both physically and electrically compatible with a test socket of an electrical testing environment. According to some configurations, the test socket interface module 340 is shaped on one side to interface with the test socket substantially as if it were the chip 110 under test. In other configurations, the test socket interface module 340 includes ports, connectors, cables, and/or other types of interfaces for coupling with other types of test sockets or for coupling with the test socket in other ways.

For example, as illustrated, the test socket interface module 340 may be tapered from the size of the carrier interface module 330 to the size of the test socket. A set of double-ended pogo pins extend through the test socket interface module 340, such that the pins protrude on either side in an arrangement that matches the test array 325. Alternatively, the test arrays 325 on either side of the test socket interface module 340 are electrically coupled internally to the test socket interface module 340.

It will now be appreciated that the assemblies and components of the interface assembly 120a can effectively provide a pin-to-pin electrical coupling between the chip 110 and an electrical testing environment (e.g., via a test socket) while presenting the circuit region 210 of the chip 110 to an optical testing environment via a prepared backside of the device. For example, the optical test assembly 310 presents the chip 110 as desired to an optical testing environment. Electrically, the original array 240 (e.g., or, technically, an analog of the original array) is translated to a derived array 315 by the optical test assembly 310; the derived array 315 is translated to a test array 325 by the carrier interface module 330 of the electrical test assembly 320; and the test array is translated by the test socket interface module 340 of the electrical test assembly 320 to an interface that is physically and electrically compatible with a test socket of an electrical testing environment. Accordingly, electrical and optical testing can be concurrently performed on the chip 110.

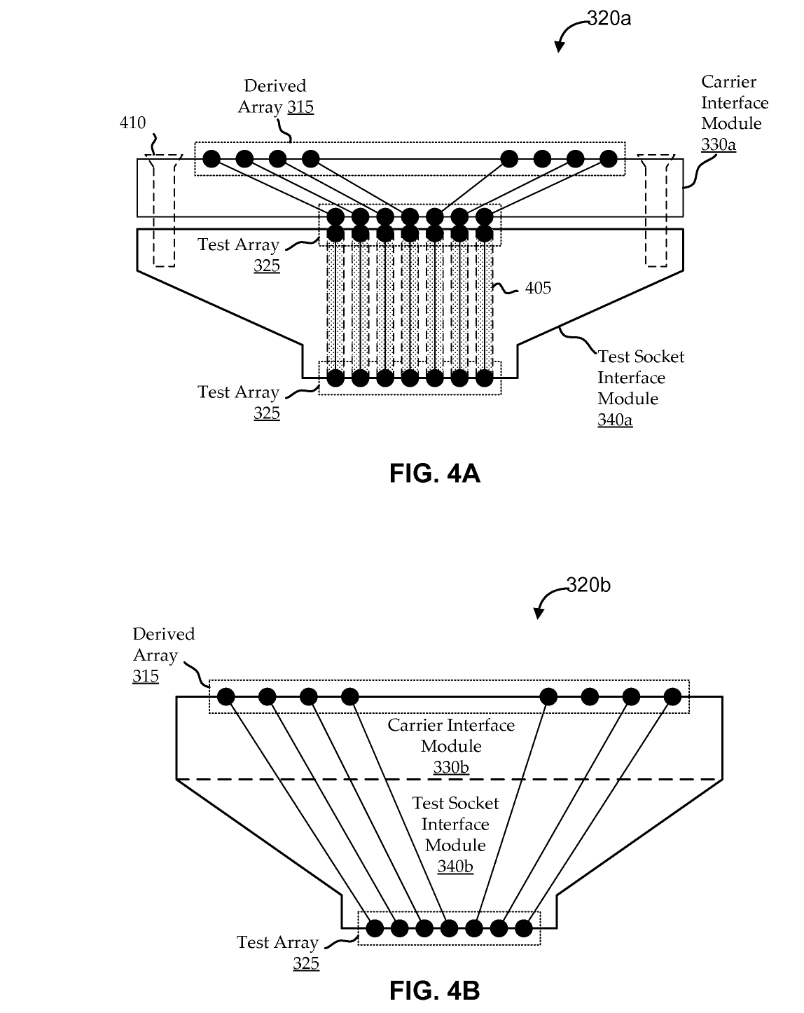

Various configurations are possible for implementing the electrical test assembly 320. FIG. 4A illustrates an exemplary configuration of an electrical test assembly 320a, like the one described with reference to FIG. 3. As discussed above, the electrical test assembly 320a electrically exposes a derived array 315 to a standard electrical interface (e.g., a test socket) of an electrical testing environment (not shown).

The electrical test assembly 320a includes a carrier interface module 330a and a test socket interface module 340a that are physically coupled as an assembly. The carrier interface module 330a translates a derived array 315 to a test array 325, and the test socket interface module 340a converts the carrier interface module 330a interface to an interface that is both physically and electrically compatible with a test socket of an electrical testing environment. Accordingly, as an assembly, the modules effectively convert the derived array 325 to a test array 325 compatible with a standard test socket.

As illustrated, the modules may be physically connected using one or more fasteners 410 (e.g., screws, clips, etc.). The fasteners 410 may physically secure the modules together, while also providing a reliable electrical coupling between the modules. For example, where one or both modules includes pogo pins 405 (e.g., or a similar coupling that extends through the test socket interface module 340a), the fasteners may provide a desired amount of clamping force for a reliable electrical coupling with the pogo pins.

FIG. 4B illustrates another exemplary configuration of an electrical test assembly 320b, like the one described with reference to FIG. 3. As with the configuration of FIG. 4A, the electrical test assembly 320b electrically exposes a derived array 315 to a standard electrical interface (e.g., a test socket) of an electrical testing environment (not shown). As illustrated by the configuration of FIG. 4B, the electrical test assembly 320b includes a carrier interface module 330b and a test socket interface module 340b that are integrated as a single device. Various types of prototyping and/or other manufacturing techniques may be used to form an electrical test assembly 320b like the one in FIG. 4B. In various configurations, depending on the process used to form the electrical test assembly 320b, the carrier interface module 330b and the test socket interface module 340 may be independently formed and joined, formed as one contiguous piece, etc.

Notably, as illustrated in FIGS. 4A and 4B, the derived array 315 may include a different number and/or configuration of array elements from that of the original array 240, and the test array 325 may be configured to form a pin-to-pin connection with the original array 240. As such, only a subset of the derived array 315 elements may be “mapped” to respective test array 325 elements. For example, a standard derived array 315, so that more chips 110 can be tested with fewer modifications to the design. Accordingly, certain reusable components may be designed to have a derived array 315 that is at least as large as needed for testing multiple types of chips 110.

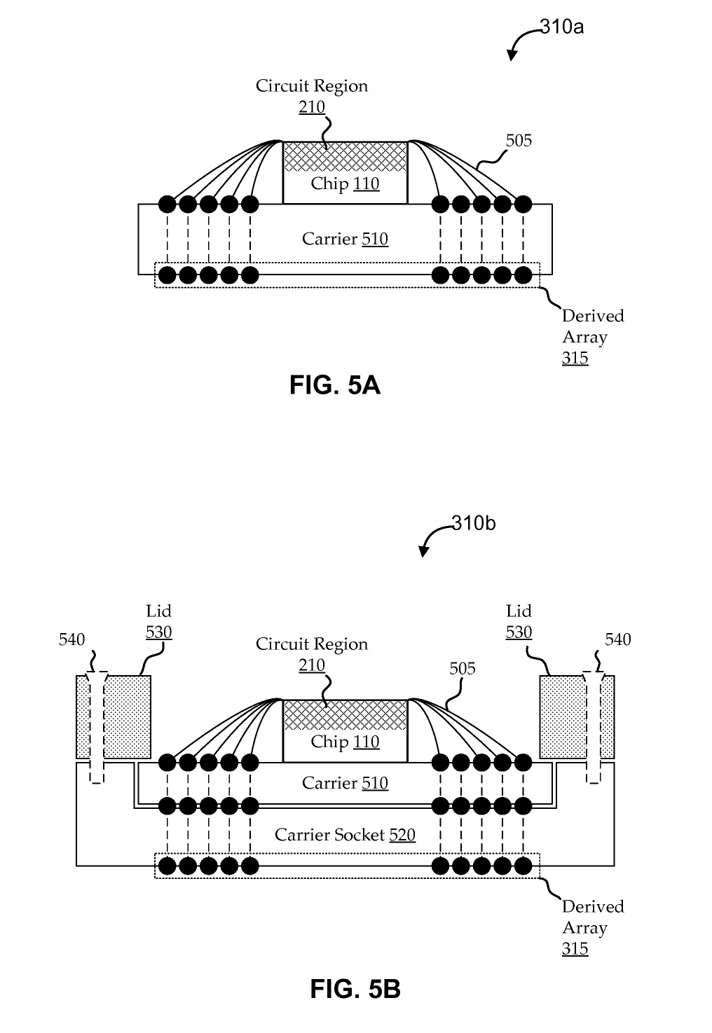

It will be appreciated that many variations are possible while still providing the desired functionality of the electrical test assembly 320. Further, many configurations are possible for implementing the optical test assembly 310. FIG. 5A illustrates an exemplary configuration of an optical test assembly 310a, like the one described with reference to FIG. 3. As discussed above, the optical test assembly 310a optically exposes a circuit region 210 of a chip 110 to an optical component (e.g., a solid immersion lens) of an optical testing environment (not shown) while electrically exposing the circuit region 210 of the chip 110 to the electrical test assembly 320.

As illustrated, the chip 110 is mounted to a carrier 510 such that a circuit region 210 of the chip 110 is exposed via its prepared backside (e.g., facing opposite the carrier 510). For example, the top side of the chip 110 is glued or otherwise physically coupled with the carrier 510. The carrier 510 may include a substrate. In some configurations, the carrier 510 is implemented as a standard PCB with a certain standard array of electrical contact elements. The array of the carrier 510 is the derived array 315.

The exposed circuit region 210 of the chip 110 includes a number of locations (e.g., according to the original array 240) for electrically interfacing with the circuit region 210 of the chip 110. These locations may be wire bonded and/or otherwise electrically coupled with respective elements of the derived array 315 using coupling elements 505 (e.g., wires, etc.). To make space for mounting the chip 110, the carrier 510 may typically be larger than the chip 110, and the derived array 315 may be larger, as well. As described above, the derived array may be converted back to a size and an interface compatible with a standard test socket of an electrical testing environment using an electrical test assembly 320 (as in FIG. 3, 4A, or 4B).

It is worth noting that the optical test assembly 310a of FIG. 5A may not provide a stable optical or electrical environment in certain cases. For example, using a PCB alone as the carrier 510 may not provide adequate stability for the optical testing environment, may not provide adequate mounting strength or space for coupling with the electrical test assembly 320, etc. FIG. 5B illustrates another exemplary configuration of an optical test assembly 310b, like the one described with reference to FIG. 3. As in the configuration of FIG. 5A, the optical test assembly 310b optically exposes a circuit region 210 of a chip 110 to an optical component of an optical testing environment while electrically exposing the circuit region 210 of the chip 110 to the electrical test assembly 320.

As in FIG. 5A, the chip 110 is mounted to a carrier 510 such that a circuit region 210 of the chip 110 is exposed via its prepared backside. The exposed circuit region 210 of the chip 110 includes a number of locations (e.g., according to the original array 240) for electrically interfacing with the circuit region 210 of the chip 110. These locations may be wire bonded and/or otherwise electrically coupled with respective elements of the derived array 315 using coupling elements 505.

Unlike in FIG. 5A, the configuration of FIG. 5B includes a carrier socket 520 and a lid 530. Configurations of the carrier socket 520 translate the derived array 315 of the carrier 510 to an interface that is large and secure enough to reliably couple with the electrical test assembly 320 and the lid 530. The lid 530 is configured to reliably couple the carrier 510 with the carrier socket 520, while leaving the circuit region 210 of the chip 110 exposed. For example, the lid 530 may effectively provide a clamping force around the periphery of the carrier 510, while having an opening (e.g., or lens or other optically accessible interface) through which the circuit region 210 of the chip 110 is exposed. In some configurations, the lid 530 is coupled with the carrier socket 520 using one or more fasteners 540. The fasters 540 may cause the lid 530 to exert sufficient pressure on the coupling between the carrier 510 and the carrier socket 520 to maintain a reliable electrical coupling between the derived arrays 315.

The carrier socket 520 may be a standard socket for receiving the carrier 510. Embodiments of the carrier socket 520 have the same array as the derived array 315 of the carrier 510. For example, the carrier socket 520 may be implemented as a 717-pin LGA-type socket. Notably, as illustrated in FIGS. 5A and 5B, the derived array 315 may include a different number and/or configuration of array elements from that of the original array 240. As such, only a subset of the original array 240 elements may be “mapped” to respective derived array 315 elements. For example, the carrier 510 may be designed to support a standard derived array 315, so that more chips 110 can be tested with fewer modifications to the design (e.g., the carrier socket 520 and the lid 530 may be reused). Accordingly, the derived array 315 of the carrier 510 may be at least as large as needed for testing multiple types of chips 110.

It will be appreciated that the optical test assembly 310 configurations described above are only some of the possible configurations. Regardless of the specific configuration, the optical test assembly 310 effectively translates the original array 240 of the chip 110 (or an analog thereof) to a derived array 315 compatible with the electrical test assembly 320, while maintaining stable optical accessibility to the circuit region 210 of the chip 110 for optical backside failure analysis. Accordingly, by coupling the optical test assembly 310 with an electrical test assembly 320 and coupling the electrical test assembly 320 with an electrical testing environment, optical and electrical testing may be concurrently performed.

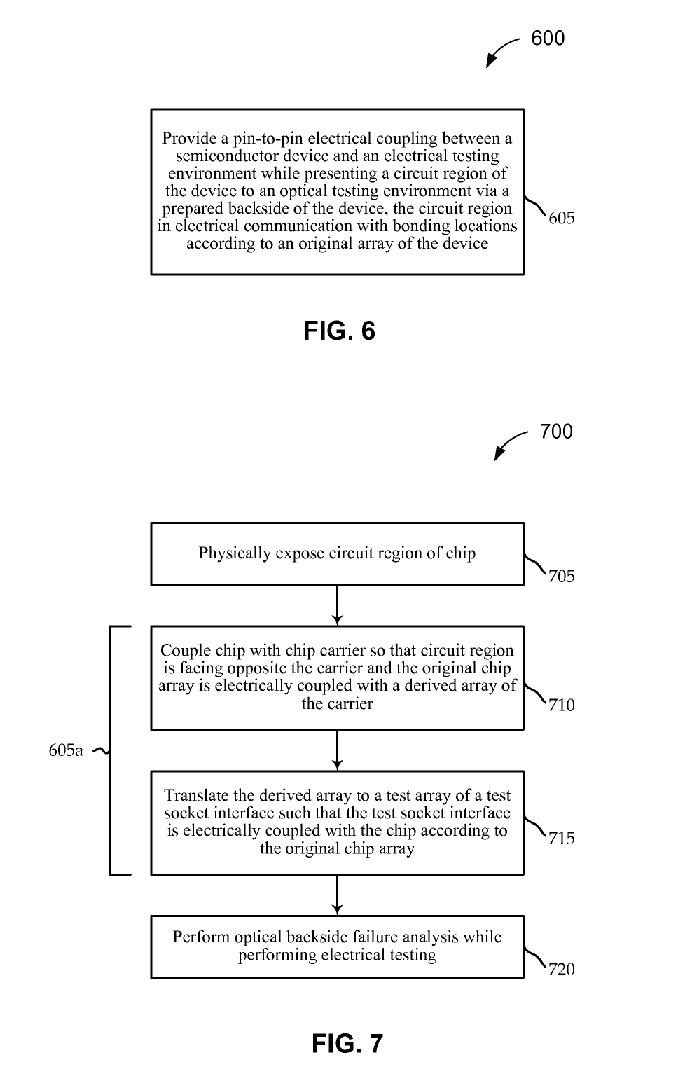

The various apparatuses (e.g., assemblies, devices, components, modules, etc.) described above can be used to perform various types of functionality. The same or similar functionality can also be performed using other types of apparatuses. Accordingly, the functionality should not be considered as limited by the specific apparatus embodiments described above. Some of the functionality is described further by the methods of FIGS. 6-8.

Turning to FIG. 6, a method 600 is described for concurrent optical and electrical testing of a semiconductor device. The method 600 includes a single stage 605, in which a pin-to-pin electrical coupling is provided between a semiconductor device and an electrical testing environment while presenting a circuit region of the device to an optical testing environment via a prepared backside of the device. As described above, the circuit region of the device can be presented to the optical testing environment via the prepared backside of the device using an optical test assembly 310, and the pin-to-pin electrical coupling between the semiconductor device and the electrical testing environment can be provided using an interface assembly 120 having the optical test assembly 310 and an electrical test assembly 320. According to some configurations, the circuit region is in electrical communication with bonding locations (i.e., on a carrier, as described above) according to an original array of the device, such that the pin-to-pin electrical coupling is between the original array and a test array of a test socket of the electrical testing environment via the bonding locations.

FIG. 7 illustrates another method 700 for concurrent optical and electrical testing of a semiconductor device that expands on the method of FIG. 6. The method 700 begins at stage 705 by physically exposing a circuit region of a chip (e.g., the semiconductor device of FIG. 6). For example, the backside of the chip is prepared so that the circuit region is visible.

At stage 710, the chip is coupled with a chip carrier so that circuit region is facing opposite the carrier and the original chip array is electrically coupled with a derived array of the carrier. For example, the topside of the chip is mounted to the carrier (e.g., a PCB) with the exposed circuit region facing away from the carrier, and locations analogous to the original array are wire bonded to the derived array of the carrier.

At stage 715, the derived array is translated to a test array of a test socket interface, such that the test socket interface is electrically coupled with the chip according to the original chip array. For example, as described above, the derived array is translated to a test array using a carrier interface module 330, and the test array is translated to an interface that is physically and electrically compatible with a standard test socket using a test socket interface module 340. In some configurations, stages 710 and 715 are implementations of an embodiment of stage 605 of FIG. 6 (indicated as stage 605a in FIG. 7).

At stage 720, optical backside failure analysis is performed while performing electrical testing. For example, optical testing equipment of an optical testing environment is optically coupled (e.g., exposed) to the exposed backside of the chip via an optical test assembly 310 while an interface of the electrical test assembly 320 is physically and electrically coupled with a test socket of an electrical testing environment.

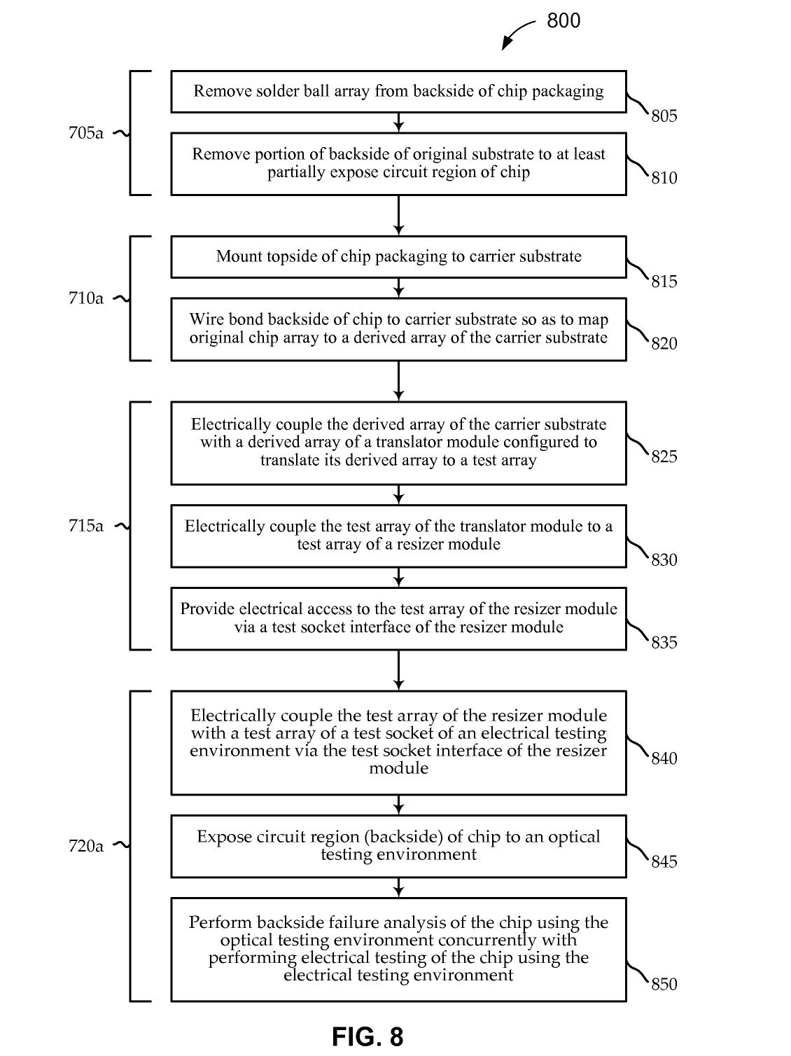

According to various embodiments, the stages of the method 700 of FIG. 7 can be expanded further. FIG. 8 illustrates another method 800 for concurrent optical and electrical testing of a semiconductor device that expands on the method of FIG. 7. Beginning at stage 705a (corresponding to an embodiment of stage 705 of FIG. 7 and including stages 805 and 810), the method 800 physically exposes a circuit region of a chip. At stage 805, a solder ball array is removed from the backside of the chip packaging. A portion of the backside of the original substrate of the chip is also removed, at stage 810, to at least partially expose circuit region of chip. For example, these stages may involve grinding, milling, polishing, and/or other techniques for carefully exposing the circuit region without damaging the circuitry under test.

The method 800 continues at stage 710a (corresponding to an embodiment of stage 710 of FIG. 7 and including stages 815 and 820), where the chip is coupled with a carrier to provide optical access to the exposed circuit region of the chip while electrically coupling the chip with a derived array of the carrier (according to the original array of the chip). At stage 815, the topside of the chip packaging is mounted to a carrier substrate. At stage 820, the backside of the chip is wire bonded (e.g., or otherwise electrically coupled) to the carrier substrate so as to map the original chip array to a derived array of the carrier substrate.

The method 800 continues at stage 715a (corresponding to an embodiment of stage 715 of FIG. 7 and including stages 825, 830, and 835), where the derived array is translated to a test array of a test socket interface, such that the test socket interface is electrically coupled with the chip according to the original chip array. At stage 825, the derived array of the carrier substrate is coupled with a derived array of a translator module (e.g., carrier interface module 330) configured to translate its derived array to a test array. The test array of the translator module is electrically coupled with a test array of a resizer module (e.g., test socket interface module 340 at stage 830. At stage 835, electrical access to the test array of the resizer module is provided via a test socket interface of the resizer module.

The method 800 continues at stage 720a (corresponding to an embodiment of stage 720 of FIG. 7 and including stages 840, 845, and 850), where optical backside failure analysis is performed while performing electrical testing. At stage 840, the test array of the resizer module is electrically coupled with a test array of a test socket of an electrical testing environment via the test socket interface of the resizer module. The circuit region of the chip is exposed to an optical testing environment at stage 845. At stage 850, backside failure analysis of the chip is performed using the optical testing environment concurrently with performing electrical testing of the chip using the electrical testing environment.

It will be appreciated that the system and method embodiments described above provide various features. One feature is that electrical testing can be performed using configurations described above by interfacing with an unmodified load board, test socket, test program, and configuration file, which may, for example, reduce cost, complexity, and maintenance duplication of dedicated failure analysis boards. Another feature is that backside failure analysis can be performed on different types of test platforms (e.g., bench test platforms, automated test equipment, system level testing, etc.) using a common configuration (e.g., of the interface assembly 120). Still another feature is that the silicon-immersion lens can make a contact with the circuit region of the chip and have enough room to move across the entire die when testing in the context of configurations described above. Even other features will be appreciated by those of skill in the art.

The various apparatuses and operations of methods described above may be performed by any suitable means capable of performing the corresponding functions. The methods disclosed herein comprise one or more steps or actions for achieving the described method. The method steps and/or actions may be interchanged with one another without departing from the scope of the disclosure or claims. In other words, unless a specific order of steps or actions is specified, the order and/or use of specific steps and/or actions may be modified without departing from the scope of the disclosure or claims.

Although the present teachings and their advantages have been described in detail, it should be understood that various changes, substitutions, and alterations can be made herein without departing from the technology of the teachings as defined by the appended claims. Moreover, the scope of the present application is not intended to be limited to the particular aspects of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding aspects described herein may be utilized according to the present teachings. Accordingly, the appended claims are intended to include within their scope such processes, machines, manufacture, compositions of matter, means, methods, or steps.

What is claimed is:

1. A system comprising:
an electrical test assembly comprising:
a carrier interface module having a first derived array on a surface physically configured to allow electrical coupling between the first derived array and a second derived array disposed on a carrier, and configured to translate the first derived array to a first test array determined according to a second test array of a test socket of an electrical testing environment; and
a test socket interface module, coupled with the carrier interface module and configured to physically couple with the test socket so as to provide an electrical coupling between the first test array and the second test array.

2. The system of claim 1, further comprising:
an optical test assembly comprising:
a carrier, physically coupled with a first side of a semiconductor device so as to present a circuit region of the device to an optical testing environment via a prepared second side of the device, the carrier being electrically coupled with the device such that the circuit region of the device is in electrical communication with bonding locations of the carrier according to an original array of the device; and
an electrical test interface configured to physically and electrically couple the second derived array with the first derived array disposed on the carrier interface of the electrical test assembly.

3. The system of claim 2, the electrical test interface comprising:
a carrier socket configured to physically and electrically couple with the carrier and to physically and electrically couple the second derived array with the first derived array disposed on the carrier interface of the electrical test assembly by providing an optical-electrical coupling region.

4. The system of claim 2, the electrical test interface comprising:
a lid configured to secure the carrier to the carrier socket so as to ensure the electrical coupling between the carrier and the carrier socket while presenting the circuit region of the device to the optical testing environment.

5. The system of claim 2, wherein the optical test assembly is coupled with the electrical test assembly to provide an electrical coupling between the bonding locations of the carrier and the second test array of the test socket.

6. The system of claim 2, wherein the optical test assembly is secured to the electrical test assembly using at least one fastener.

7. The system of claim 2, wherein the optical testing environment is configured for optical backend failure analysis.

8. The system of claim 2, wherein the first derived array is substantially identical to the second derived array, is larger than the original array of the device, and is arranged according to a standard array configuration.

9. The system of claim 1, wherein the test socket interface module is coupled with the carrier interface module and configured to physically couple with the test socket so as to provide a pin-to-pin electrical coupling between the first derived array and the second test array.

10. The system of claim 1, wherein the carrier interface module comprises a circuit board having:
a first plurality of electrical interface elements arranged according to the first derived array disposed on a first side of the circuit board;
a second plurality of electrical interface elements arranged according to the first test array disposed on a second side of the circuit board; and
an electrical coupling between each of the second plurality of electrical interface elements and a corresponding one of the first plurality of electrical interface elements.

11. The system of claim 10, wherein the circuit board is a 717 LGA board.

12. The system of claim 1, wherein the test socket interface module comprises:
a plurality of pins, arranged according to the second test array, extending through a housing, and protruding from each of a first side and a second side of the housing, the first side of the housing configured to physically couple with the carrier interface module to provide an electrical coupling between each of the plurality of pins and a corresponding element of the first test array, and the second side of the housing configured to physically couple with the test socket to provide an electrical coupling between each of the plurality of pins and a corresponding element of the second test array.

13. The system of claim 1, wherein the test socket interface module is integrated with the carrier interface module.

14. The system of claim 1, wherein the test socket interface module is secured to the carrier interface module using at least one fastener.

15. The system of claim 1, wherein the device is a wire-bonded semiconductor device, the second side of the device being prepared by removing a portion of the second side of the device including a solder ball array configured according to the original array of the device.

16. The system of claim 1, wherein the second test array is substantially identical to the original array of the device.

17. A system comprising:
means for providing a pin-to-pin electrical coupling between a semiconductor device and an electrical testing environment while presenting a circuit region of the device to an optical testing environment via a prepared backside of the device, the circuit region in electrical communication with bonding locations according to an original array of the device.

18. The system of claim 17, wherein the means for providing a pin-to-pin electrical coupling between the semiconductor device and the electrical testing environment while presenting the circuit region of the device to the optical testing environment comprises:
means for physically coupling with the device so as to present the exposed circuit region of the device to the optical testing environment while electrically coupling the bonding locations of the device with a derived array;
means for physically interfacing with a test socket of the electrical testing environment while electrically coupling with a test array of the test socket; and
means for electrically translating the derived array to the test array, such that the bonding locations of the device are electrically coupled with the test socket of the electrical testing environment.

19. The system of claim 18, wherein the test socket is configured to directly interface with a packaging of the device via a pin-to-pin electrical coupling between the test array and the original array of the device presented via the packaging.

20. The system of claim 19, wherein the original array of the device is presented via the packaging as a solder ball array.

21. The system of claim 18, further comprising:
means for securing the means for physically interfacing with the test socket of the electrical testing environment while electrically coupling with the test array of the test socket to the means for electrically translating the derived array to the test array.

22. The system of claim 18, wherein the means for physically coupling with the device so as to present the exposed circuit region of the device to the optical testing environment while electrically coupling the bonding locations of the device with a derived array comprises:
means for physically coupling a topside of the device with a first side of a carrier; and
means for electrically coupling each bonding location of the device to one of a plurality of bonding locations on a first side of the carrier, each bonding location on the first side of the carrier being in electrical correspondence with an electrical interface element on the second side of the carrier arranged according to the derived array.

23. The system of claim 22, wherein:
the means for electrically translating the derived array to the test array comprises:
a carrier interface comprising a plurality of electrical interface elements arranged according to the derived array and configured to interface with the second side of the carrier so as to electrically couple each electrical interface element of the carrier interface with a corresponding one of the electrical interface elements of the second side of the carrier; and
a first intermediate interface comprising a plurality of electrical interface elements arranged according to the test array, each electrical interface element of the first intermediate interface being electrically coupled with a corresponding one of the electrical interface elements of the carrier interface; and
the means for physically interfacing with the test socket of the electrical testing environment while electrically coupling with the test array of the test socket comprises:
a second intermediate interface comprising a plurality of electrical interface elements arranged according to the test array and configured to interface with the first intermediate interface so as to electrically couple each electrical interface element of the second intermediate interface with a corresponding one of the electrical interface elements of the first intermediate interface; and
a socket interface comprising a plurality of electrical interface elements arranged according to the test array, each electrical interface element of the socket interface being electrically coupled with a corresponding one of the electrical interface elements of the second intermediate interface.

24. A method comprising:
providing a pin-to-pin electrical coupling between a semiconductor device and an electrical testing environment while presenting a circuit region of the device to an optical testing environment via a prepared backside of the device, the circuit region in electrical communication with bonding locations according to an original array of the device.

25. The method of claim 24, wherein providing the pin-to-pin electrical coupling between the semiconductor device and the electrical testing environment while presenting the circuit region of the device to the optical testing environment comprises:
physically coupling with the device so as to present the exposed circuit region of the device to the optical testing environment while electrically coupling the bonding locations of the device with a derived array;
physically interfacing with a test socket of the electrical testing environment while electrically coupling with a test array of the test socket; and
electrically translating the derived array to the test array, such that the bonding locations of the device are electrically coupled with the test socket of the electrical testing environment.

26. The method of claim 25, further comprising:
securing a test socket interface module to a carrier interface module,
wherein the physically interfacing step is performed using the test socket interface module and the electrically translating step is performed using the carrier interface module.

27. The method of claim 25, wherein physically coupling with the device so as to present the exposed circuit region of the device to the optical testing environment while electrically coupling the bonding locations of the device with a derived array comprises:
physically coupling a topside of the device with a first side of a carrier; and
electrically coupling each bonding location of the device to one of a plurality of bonding locations on a first side of the carrier, each bonding location on the first side of the carrier being in electrical correspondence with an electrical interface element on the second side of the carrier arranged according to the derived array.

28. The method of claim 24, further comprising:
preparing the backside of the device by removing a portion of the backside of the device including a solder ball array configured according to the original array of the device.
